(19) United States
(12) Patent Application Publication
(10) Pub. No.: US 2023/0060182 A1
(43) Pub. Date: Mar. 2, 2023

(54) MODULAR LIGHTED DISPLAY PANEL ASSEMBLIES

(71) Applicant: AmpThink, LLC, Garland, TX (US)

(72) Inventors: Thomas POWELL, Wylie, TX (US); William C. ANDERSON, III, Dallas, TX (US)

(21) Appl. No.: 17/822,426

(22) Filed: Aug. 25, 2022

Related U.S. Application Data
(60) Provisional application No. 63/236,754, filed on Aug. 25, 2021.

(51) Int. Cl. F21V 8/00

(52) U.S. Cl. CPC G02B 6/0086; G02B 6/0073; G02B 6/006

(57) ABSTRACT

Modular lighted display panel assemblies are disclosed that are used to provide modular lighted signage in various applications. The modular lighted display panel assemblies may be linked in a serialized fashion in certain implementations shown herein. In one particular implementation described herein, modular lighted display panel assemblies are linked to provide digital signage on a series of server racks. The techniques described herein allow implementation of some panels without the additional cost and complexity of power modules and/or lighting modules.

### BACKGROUND

Signage has always been an important factor in displaying information to consumers about a particular product. In recent years, digital signage and lighted signage has developed as a more attractive and more efficient way to reach consumers and/or to display communications. As a new application is identified, technical problems are encountered that must be overcome to implement the new application.

### SUMMARY

Modular lighted display panel assemblies are disclosed that are used to provide lighted modular signage in various applications. The modular lighted display panel assemblies may be linked in a serialized fashion in certain implementations shown herein. In one particular implementation described herein, modular lighted display panel assemblies are linked to provide digital signage on a series of server racks. Some components are not required on certain display panels, enabling economical manufacturing and implementation of the module lighted display panel assemblies.

### BRIEF DESCRIPTION OF THE DRAWINGS

A particular description of the principles briefly described above will be rendered by reference to specific embodiments thereof, which are illustrated in the appended drawings. Understanding that these drawings depict only certain exemplary embodiments of the disclosure and are not therefore to be considered to limit its scope, the principles herein are described and explained with additional specificity and detail through the use of the accompanying drawings.

FIG. 1 is a depiction of a server rack assembly wherein each server rack includes a lighted display assembly that displays a name.

FIG. 2 is an exploded diagram of an example modular lighted display panel assembly.

FIG. 3 depicts a front and rear view of multiple lighted panel assemblies linked together.

FIG. 4 depicts a linkable lighted panel assembly that includes a power module but no DMX module.

### DETAILED DESCRIPTION

The apparatuses and techniques describe herein relate to linkable modular lighted display panel assemblies. More particularly, the disclosures contained herein related to digital signage in server racks, said digital signage incorporating linked modular lighted display panel assemblies.

Many businesses have a need for a large IT operation, and most such businesses have invested substantial sums of money in building data centers to support their IT operations. Such data centers include from one to multiple servers. Often, such business owners/operators take customers, potential customers, employees, potential employees, etc. on tours through their data center as part of a sales or recruiting process or to show off the investment the business has made in IT. While data center installations have an impressive light show inherent in the server hardware, such installations are drab and tend to look like all other data centers. Data centers currently do not allow for projecting a brand or other important information that a business owner would like to communicate to a business partner or employee. IT vendors strive to make their installations functional, but many also work to make server installations aesthetically pleasing. One technique that is used is to fill empty rack spaces with a blank cover panel to provide a more finished appearance.

The solutions disclosed herein provide IT installers an option to provide a striking visual impact for data center owners using an assembly that can easily be used from project to project. The techniques disclosed herein use a standard lighting control protocol (DMX), a simple and reliable interconnect system, a flexible and scalable platform, and a manufacturing process that allows systems to be customized for each job. In at least one implementation, lighting control is driven over a standard Ethernet connection with panel assemblies serialized using a simple 4-wire harness.

Panel assemblies utilize four types of units:
A base panel delivers a backlit logo/design panel that delivers a brand and/or message backed by a customizable light show. DMX controlled strip lighting embedded in the base panel can be incorporated into existing lighting control platforms or operated as a standalone system when coupled with power or control panels.
A power panel adds a power supply to the base panel to provide a power source for a chain of base panels. Power panels can be flexibly integrated into a chain of base plates to allow the size of the system to scale. The number of power panels required is determined by the number of LEDs in each panel. Larger panels incorporate more LEDs requiring more power per panel. In at least one embodiment, one power panel is used for every 5 4-panel units, 1 power panel plus 4 base panels. Smaller 2-panel units or as large as a 12-panel unit may also be implemented.
A control panel adds a DMX controller to a power panel. The Ethernet based controller is a perfect option for standalone systems or as an extension of larger lighting control solution that requires a local controller to augment existing control strings. The Control panel is an all in one starter panel that includes power, light control, and signage.
Blank panels can be provided in a range of standard configurations (1-panel, 2-panel, 4-panel, and 12-panel) and can be finished in a wide range of durable powder coated finishes to match server rack aesthetics. Blank panels can also be screen printed for additional non-lighted signage. Blank panels may or may not include a cable connector, depending on the implementation.

Wiring Harnesses. Building a lighting system that delivers an exciting visual experience requires the ability to coordinate color transitions across multiple panels while opportunistically adding power to deliver constant brightness. It also requires careful power planning as incorrect connections result in fried controllers and burnt out LEDs. The interconnect harnesses shown herein eliminate the guess work from server rack projects. Each interconnect harness is unidirectional and leverages connectors that can only be connected only in one way to avoid damaging the strip lighting or controls. Additionally, interconnect harnesses can be of different lengths to support clean inter-rack and intra-rack layouts.

Power Solution. Distance and connectors introduce voltage drop. Voltage drop is a problem for two reasons: first, voltage drop causes the LEDs to dim; secondly, under-powering the LED reduces the useful life of the LED. The solution disclosed herein involves injecting the power into a power header/connector that includes the ability to pass through control cables in the same connection. The power-enabled header can be added with the controller (control panel) or anywhere it is needed in a string of panels via the power panel. In one implementation, the current power panel utilizes a 120 VAC connection to drive the transformer which pushes power into an LED light strip that provides lighting to a panel. Implementations may also utilize a PoE (Power over Ethernet) powered equivalent. Using PoE is well-matched to installation in a data rack. PoE would also allow for a single cable connection to a control panel.

The wiring harness is decoupled from the panels. By de-coupling the wiring harness, providing custom length cables between panels is simpler. A standard panel can be built without consideration of the cable length needed on a per project basis. If all panels are in a single rack, short cables are ideal (note again that cable length/voltage drop are a problem). When the installation involves panels spread around a data center, longer cables are required. The decoupling is also significant to the incorporation of power and control systems. Adding both or either simply requires a different cable assembly. Here again, modularity allows the building of a singular base panel which eliminates the need to support multiple panel variants in the manufacturing process.

There is a simple way to eliminate the extrusion to end up with a translucent plate (e.g., LED/polycarbonate) to be encapsulated in panel assemblies. The configuration of a back plate which achieves that and also incorporates the field of fasteners required allows power and control modules to be easily added.

In most implementations, each panel has a fixed number of LEDs. This is partially driven by the fact that the LEDs are evenly spaced, and the size of each panel is one of a range of standard sizes. However, small inconsistencies can be introduced if the LED count is one LED off in one or more other implementations. The control system needs to know which LED is being controlled to execute visual effects. By having a standard LED count in each panel size, reliable system control can be delivered to a user. While compensation for a greater variance may be made, the standardization of LED counts further simplifies implementation.

In at least one implementation, each panel installs in the rack using standard rack screws, but those could be replaced by use of a simple toolless fastener. Thus, a captive fastener system can be incorporated to eliminate the need to screw these panels into the rack. Instead, the panels would just pop in.

In at least one other implementation, the system doesn't even require that the fastener be inserted into an existing rack screw hole. Instead, it would grab the internal edges of rack assembly allowing the panel to be slid up or down. Often, after equipment is located in a rack, gaps left don't always perfectly align with the remaining screw holes. By allowing a panel to slide up and down, the panel can be tightly aligned with existing equipment. This feature applies equally to illuminated and blank rack panels.

A power switch/button may be added to the assembly. LED consumes a fairly significant amount of energy. The current control system assumes that on/off is controlled via DMX. Adding a power switch to the control and/or power panel would offer a simple mechanism for turning the lighting on and off. Some users might want to turn the system off when there are no visitors planned.

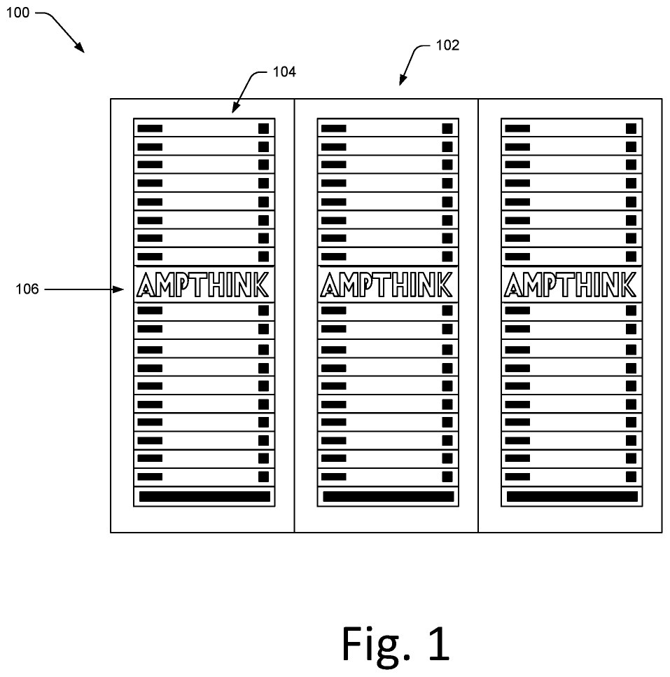

FIG. 1 is a depiction of a server rack assembly 100 in accordance with the current disclosure. The server rack assembly 100 includes three server racks 102, although any number of server racks may be used with the present techniques. Each server rack 102 includes a plurality of servers 104. Each server rack 102 also includes a lighted panel assembly 106 that displays a signage message such as a company name or other word, phrase, or design. Although the present example shows each server rack 102 including a lighted panel assembly 106, other implementations may include any number lighted panel assemblies 106 without regard for a number of server racks 102. For instance, in the present example, one implementation may include only one server rack 102 that includes a lighted panel assembly 106.

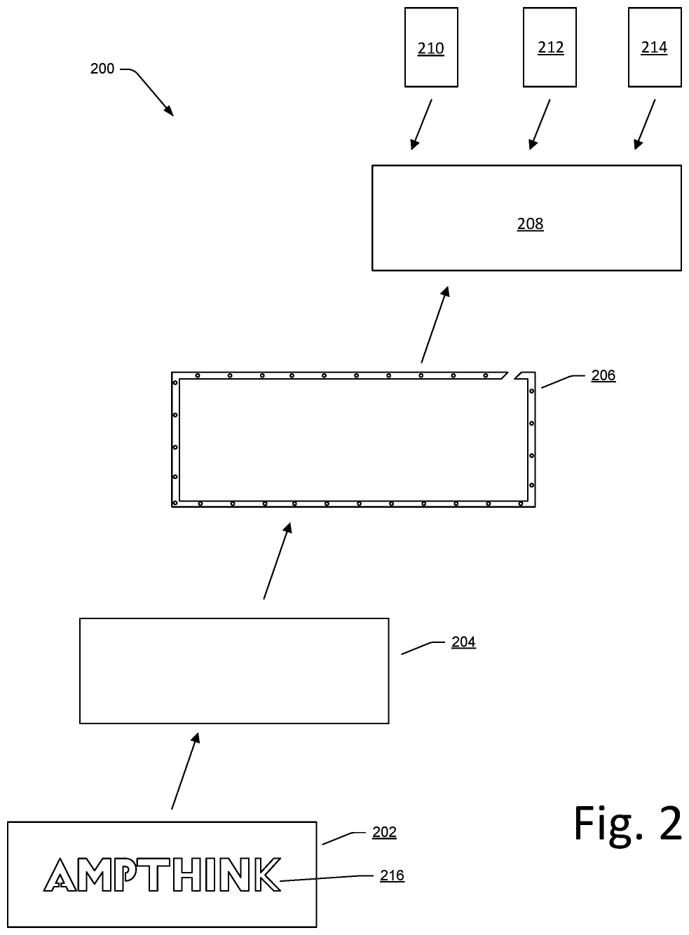

FIG. 2 is an exploded diagram of an example lighted display panel 200. The example lighted display panel includes a front plate 202, a translucent plate 204, an LED lighting strip 206, and a back plate 208. Different combinations of components—a power unit 210, a lighting controller 212, and a cable connector 214—may be attached to the back plate 208 depending on the desired use of the lighted display panel.

The front plate 202 is typically made of an opaque or at least semi-opaque material and has a signage message 216 cut out of the material. When the front 202 plate is backlit, the signage message 216 is clearly displayed in a light or dark environment.

The translucent plate 204 is formed from a material that is transmits light to some extent. The LED lighting strip 206 wraps around a perimeter of the translucent plate 204 so that light emitted from the LEDs on the LED lighting strip 206 is diffused throughout the translucent plate 204 and, ultimately, through the signage message that is cut out of the front plate 202.

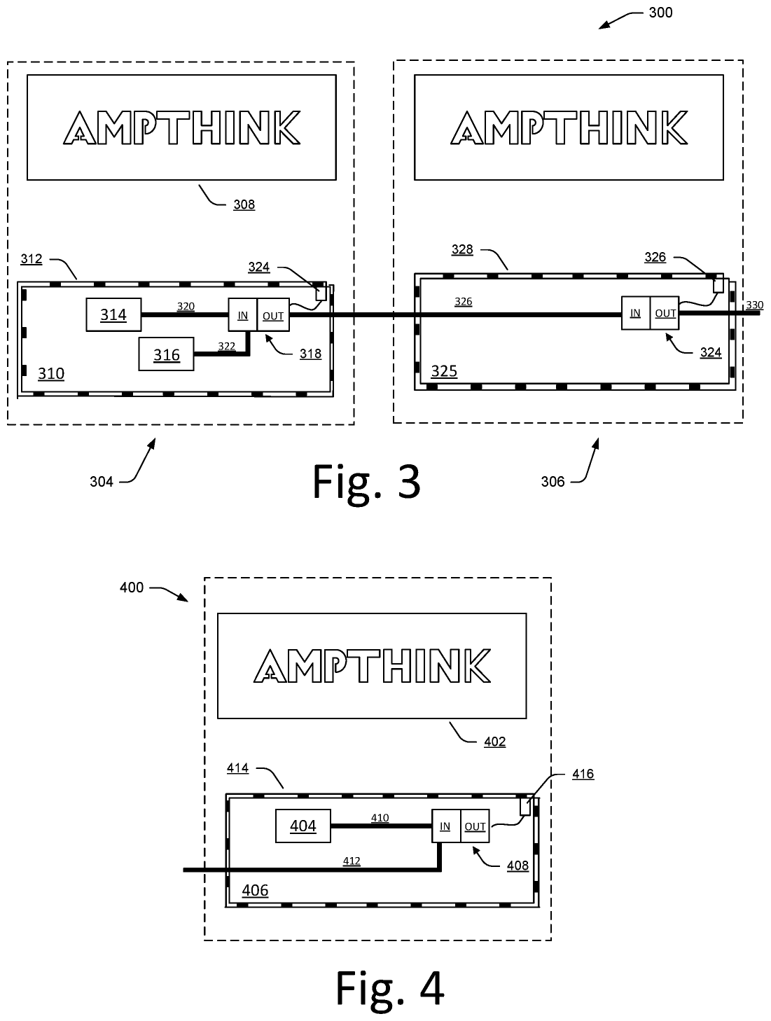

The back plate 208 serves to provide a structural backing to the lighted display panel 200 and to serve as an attachment point for one or more components (210, 212, 214) on a back side of the back plate 208, which keeps the components (210, 212, 214) out of view from a front view of the lighted display panel 200. Although shown with three components—the power unit 210, the lighting controller 212, and the cable connector 214—some lighted display panels 200 will contain only one or two of the components. Further, in at least one implementation, a blank panel may be used that is implemented without any of the components attached to the back plate 208. Further details of the different combinations of components used in the lighted display panels 200 is shown and explained in FIG. 3 and FIG. 4.

FIG. 3 depicts a front and rear view of multiple lighted panels that are shown linked together in a lighted display panel assembly 300. The lighted display panel assembly 300 includes a first panel 304 (a control panel) and a second panel 306 (base panel). The first panel 304 includes a front plate 308, and a back plate 310. The first panel 304 also includes a translucent plate but it is not shown in FIG. 3. An LED strip 312 that surrounds the translucent plate (not shown) can be seen. The first panel 304 includes a power unit 314, a lighting controller 316, and a cable connector 318 that accommodates input and output. A power cable (not shown) connects to the power unit 314 to provide power to the first panel 304. A first cable 320 connects the power unit 314 to the cable connector 318. A second cable 322 connects the lighting controller 316 to the cable connector 318, which provides connections for power and data cables. The cable connector 318 is also connected to an LED strip connector 324 to provide power to the lighting for the first panel 304.

The second panel 306 is a base panel that includes a cable connector 324 attached to a back plate 325 of the second panel 306. A connecting cable 326 connects the cable connector 318 in the first panel 304 to the cable connector 324 in the second panel 306. The cable connector 324 of the second panel 306 is connected to an LED strip connector 326 to power an LED strip 328 included in the second panel 306. A continuation cable 330 is connected to the cable connector 324 of the second panel 306 and, although not shown in FIG. 3, may connect the second panel 306 to an additional panel (not shown).

FIG. 4 depicts a linkable lighted panel assembly 400 (power panel) that includes a front plate 402 and a power module 404 connected to a back plate 406. Note that no lighting controller module is included in the lighted panel assembly 400. A power module can typically provide power to a fewer number of panels that a lighting (DMX) module can control. Therefore, the lighted panel assembly 400 may be linked to a control panel (not shown) in a system that has lighting effects. In one or more alternate implementations, the lighted panel assembly 400 may be used in a system without a lighting (DMX) module if no special lighting effects are desired.

The lighted panel assembly 400 includes a cable connector 408 that receives a power cable 410 from the power module 404 and a lighting cable 412 if used in a system having lighting effects. If implemented, the lighting cable 412 will be connected, directly or indirectly, to a lighting control module (not shown) in another panel (not shown). An LED light strip 414 surrounds a translucent plate (not shown) in the lighted panel assembly 400. The LED light strip 414 is connected to an LED strip connector 416 that receives power through the cable connector 408. Although not shown in this particular depiction, the lighted panel assembly 400 may be linked to another lighted panel assembly (not shown) by way of a cable (not shown) from the cable connector 408 to the other lighted panel assembly (not shown).

While the modular lighted display panel assemblies are described with respect to certain embodiments and/or generally associated methods, alterations and permutations of these embodiments and application to any application, a person having ordinary skill in the art will recognize other applications in which the presently described technology may be used. Accordingly, the above description of example embodiments does not define or constrain this disclosure. Other changes, substitutions, and alterations are also possible without departing from the spirit and scope of this disclosure, as defined by the following claims.

1. A lighted panel module, comprising:
a front plate having a signage message cutout therefrom;
a translucent plate;
a light source;
a back plate;
a cable connector affixed to the back plate that connects the lighted panel module to a cable connector of another lighted panel module.

2. The lighted panel module as recited in claim 1, wherein the light source is an LED strip that projects light through the translucent plate.

3. The lighted panel module as recited in claim 1, further comprising a power source.

4. The lighted panel module as recited in claim 3, wherein the power source is affixed to the back plate.

5. The lighted panel module as recited in claim 1, further comprising a lighting controller.

6. The lighted panel module as recited in claim 1, further comprising a power source and a lighting controller.

7. A server rack in which a lighted panel module as described in claim 1 is mounted.

8. A server rack assembly, comprising:
a first server rack and a second server rack;
a lighted panel module mounted in each of the first server rack and the second server rack;
a connecting cable that connects the lighted panel module of the first server rack to the lighted server module of the second server rack;
wherein each lighted panel module further comprises:
a front plate having signage message integrated therein;
a translucent plate;
a lighting strip that, when powered, transmits light through the translucent plate to illuminate the signage message;
a back plate on which one or more components are mounted.

9. The server rack assembly as recited in claim 8, further comprising a power unit mounted to the back plate.

10. The server rack assembly as recited in claim 8, further comprising a lighting control module mounted to the back plate.

11. The server rack assembly as recited in claim 8, further comprising a power unit and a lighting control module mounted to the back plate.

12. The server rack assembly as recited in claim 8, wherein the lighted panel module included in the first server rack further comprises a power unit and a lighting control module.
